(19) United States
(12) Patent Application Publication
(10) Pub. No.: US 2006/0292817 A1
(43) Pub. Date: Dec. 28, 2006

(54) Methods of processing semiconductor structures and methods of forming capacitors for semiconductor devices using the same

(75) Inventors: Cheol-Woo Park, Suwon-si (KR); Yong-Sun Ko, Suwon-si (KR); Byoung-Moon Yoon, Suwon-si (KR); Kyung-Hyun Kim, Seoul (KR); Kwang-Wook Lee, Seongnam-si (KR); Chang-Gil Ryu, Yongin-si (KR); Sung-Ho Ha, Haeundae-gu (KR); Woo-Suck Song, Cheonan-si (KR); Yong-Myung Jun, Suwon-si (KR); Seung-Yul Park, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/452,409

(22) Filed: Jun. 14, 2006

(30) Foreign Application Priority Data
Jun. 16, 2005 (KR) 10-2005-0052024

(51) Int. Cl. H01L 21/20

(52) U.S. Cl. 438/396

(57) ABSTRACT

In a method of processing a semiconductor structure and a method of forming a capacitor for a semiconductor device using the same, a semiconductor structure may be cleaned using a cleaning solution having a surface tension lower than that of water. The semiconductor structure may be dried in an isopropyl alcohol vapor atmosphere.

### PRIORITY STATEMENT

This non-provisional patent application claims priority under 35 U.S.C. § 119 to Korean Patent Application No. 10-2005-0052024 filed on Jun. 16, 2005 in the Korean Intellectual Property Office (KIPO), the entire contents of which are incorporated herein by reference.

### BACKGROUND

1. Field of the Invention

Example embodiments of the present invention relate to methods of processing semiconductor structures and methods of forming capacitors for semiconductor devices using the same, for example, methods of processing semiconductor structures such as cylindrical lower electrodes and methods of forming capacitors for semiconductor devices using the same.

2. Description of the Related Art

Related art dynamic random access memory (DRAM) devices may have a unit cell including an access transistor and a storage capacitor. Increased integration of semiconductor devices may require a smaller storage capacitor. Recent methods for manufacturing semiconductor devices have formed capacitors with larger storing capacitance and/or reduced size.

Capacitance C of a capacitor is expressed as the following equation (1).

$$C = {ɛ}_{0} ɛ \frac{A}{d} \qquad ( 1 )$$

In the above equation (1), ε₀ represents a dielectric constant of a vacuum and ε represents a dielectric constant of a dielectric layer of a capacitor. ‘A’ represents an effective surface area of a lower electrode and ‘d’ represents a thickness of the dielectric layer.

As shown in equation (1), storage capacitance of a capacitor may be directly proportional to an effective surface area of a lower electrode and a dielectric constant of a dielectric layer and may be inversely proportional to a thickness of a dielectric layer. Thus, according to the equation (1), an increase in the effective surface area of a lower electrode may be used for increasing the storage capacitance. For example, a lower electrode of a capacitor may be formed into a cylindrical shape having a larger height than width such that a surface area of the lower electrode is increased.

FIG. 1 is a cross sectional view illustrating a lower electrode of a related art capacitor for a semiconductor device. As shown, a plurality of cylindrical lower electrodes 16 may be formed on a semiconductor substrate 10. Each of the cylindrical lower electrodes 16 may have a larger height than width and may be arranged on the substrate close to each other. A cylindrical lower electrode 16 having a larger height than width may have a higher aspect ratio. An insulation interlayer 12 may be formed on the substrate 10 and a contact pad 14 may be formed into the insulation interlayer 12. The cylindrical lower electrode 16 may contact the contact pad 14.

A mold layer (not shown) having an opening may be used to form the cylindrical lower electrode 16. The mold layer having an opening may be formed on the substrate 10, and a thin layer may be formed (e.g., continuously formed) on a surface of the mold layer, sidewalls and bottom of the opening. The thin layer may be separated by a cell unit through a node separation process, and the mold layer may be completely removed from the substrate 10. The node-separated thin layer may be formed into a cylindrical lower electrode for a capacitor on the substrate 10.

The mold layer may be generally removed from the substrate 10 by a wet etching process using a solution of Limulus Amoebocyte Lysate (LAL), which is a mixture of ammonium fluoride (NH4F), hydrogen fluoride (HF) and water (H₂O). A cleaning process and a dry process may be performed on the substrate 10 after the wet etching to remove the mold layer for removing a residual LAL solution. The residual LAL solution may be removed from a resultant structure including the cylindrical lower electrode 16 by using pure water, and the resultant structure including the cylindrical lower electrode 16 may be dried for evaporating the pure water remaining on the resultant structure.

The cylindrical lower electrode 16 may be broken and/or leaning against another lower electrode when the resultant structure including the cylindrical lower electrode 16 is dried. The broken and/or leaning lower electrode 16 may cause a two-bit failure in which two neighboring lower electrodes 16 contact with each other. The breaking and/or leaning of the lower electrode 16 may be caused by the water 18. For example, the water may be interposed between the neighboring lower electrodes 16, and the neighboring lower electrodes 16 may be attracted to each other by a surface tension of the water. The surface tension of water is about 72.75 dyne/cm at a temperature of about 20° C., which may be sufficient to attract the neighboring lower electrodes at room temperature.

### SUMMARY OF THE INVENTION

At least some example embodiments of the present invention provide methods of processing semiconductor structures and/or capacitors for semiconductor devices, which may suppress (e.g., prevent) various processing failures such as a two-bit failure caused by the breaking and/or leaning of the neighboring patterns. The semiconductor structure including the patterns having a higher aspect ratio may be more stably manufactured and/or defects caused by the breaking and/or leaning of the neighboring patterns may be suppressed.

At least one example embodiment of the present invention provides a method for processing a semiconductor structure. The semiconductor structure may be cleaned using a cleaning solution having a surface tension lower than that of water. The semiconductor structure may be dried in an isopropyl alcohol vapor atmosphere. In at least some example embodiments of the present invention, the semiconductor structure may include a plurality of patterns having a higher aspect ratio and/or be arranged closer to each other.

At least one other example embodiment of the present invention provides a method of forming a capacitor for a semiconductor device. A mold layer may be formed on a semiconductor substrate. The mold layer may include an opening through which the substrate may be at least partially exposed. A thin layer may be formed (e.g., continuously formed) on a surface of the mold layer, a sidewall of the opening and a top surface of the substrate exposed through the opening. A sacrificial layer is formed on a resultant structure including the thin layer. The sacrificial layer and the thin layer may be removed (e.g., sequentially removed) until the surface of the mold layer is exposed so that the sacrificial layer and the thin layer remain in the opening and the thin layer is separated by a node of a unit cell of the semiconductor device. The mold layer and a residual sacrificial layer remaining in the opening may be removed from the substrate transforming the node-separated thin layer into a lower electrode. The substrate on which the lower electrode is formed may be cleaned using a cleaning solution having a surface tension lower than that of water. The substrate on which the lower electrode is formed may be dried in an isopropyl alcohol vapor atmosphere. A dielectric layer may be formed on the lower electrode, and an upper electrode may be formed on the dielectric layer.

According to at least some example embodiments of the present invention, the semiconductor structure may include patterns having a higher aspect ratio such as a lower electrode or cylindrical lower electrode. The semiconductor structure may be cleaned using a cleaning solution having a surface tension lower than that of water, and neighboring patterns may be less attracted to each other because the surface tension of the cleaning solution is insufficient for mutual attraction of the neighboring patterns.

### BRIEF DESCRIPTION OF THE DRAWINGS

The present invention will become readily apparent by reference to the example embodiments as discussed herein and the accompanying drawings, in which:

FIG. 1 is a cross sectional view illustrating a lower electrode of a related art capacitor for a semiconductor device;

FIG. 2 is a partially enlarged view of portion II in FIG. 1;

FIGS. 3A to 3I are cross sectional views illustrating a method of forming a capacitor for semiconductor devices according to an example embodiment of the present invention;

FIG. 4 is a graph showing a relation of the surface tension of a diluted isopropyl alcohol as a function of concentration;

FIG. 5 is structural view illustrating a pre-cleaning bath for pre-cleaning a substrate including a cylindrical lower electrode according to an example embodiment of the present invention; and

FIG. 6 is structural view illustrating a processing chamber for drying a substrate including a cylindrical lower electrode in an isopropyl alcohol vapor atmosphere according to an example embodiment of the present invention.

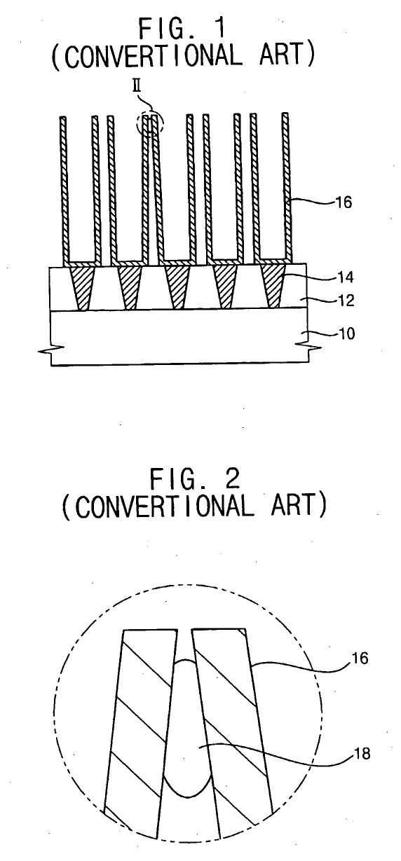

### DETAILED DESCRIPTION OF EXAMPLE EMBODIMENTS OF THE PRESENT INVENTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

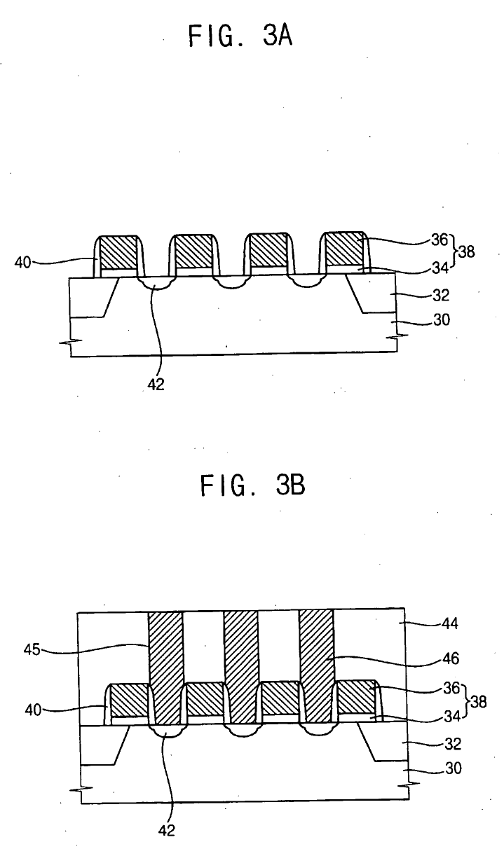

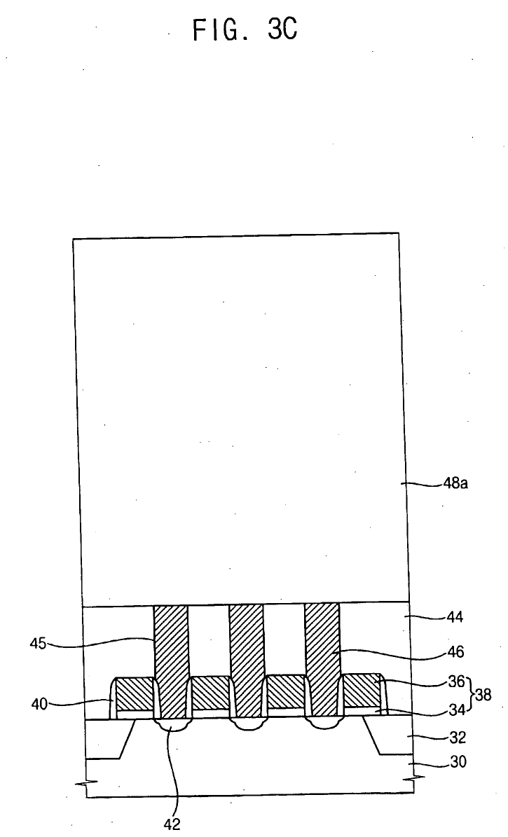

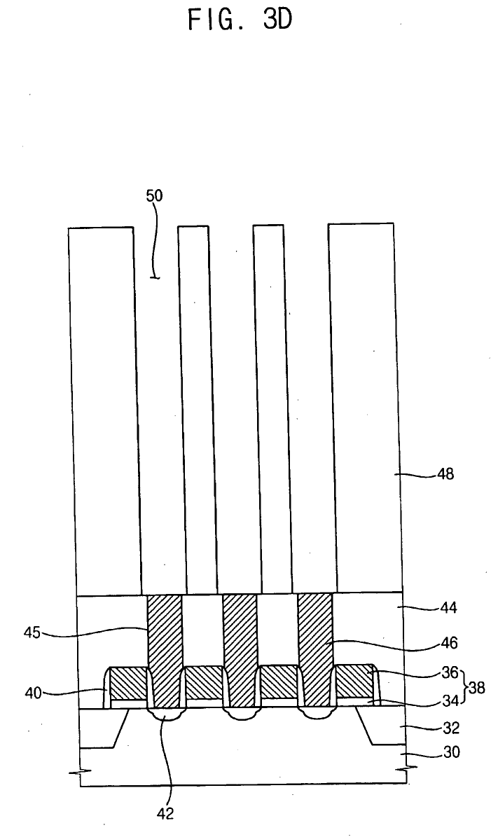

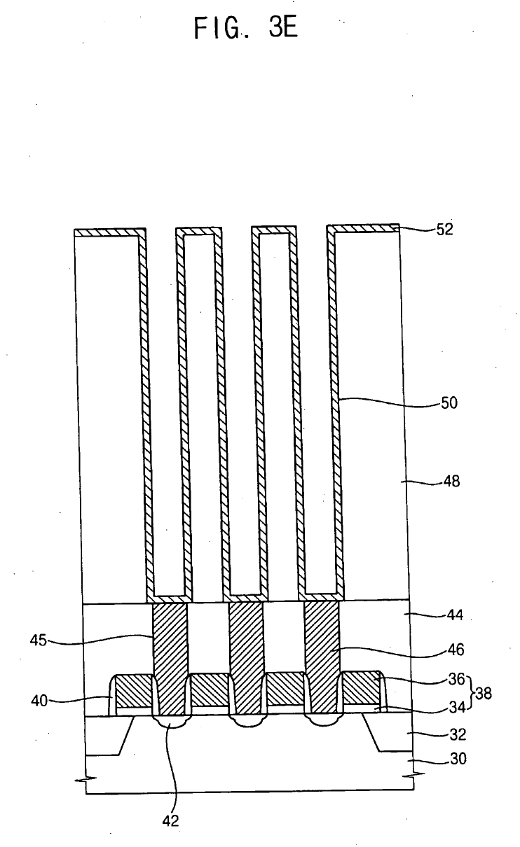

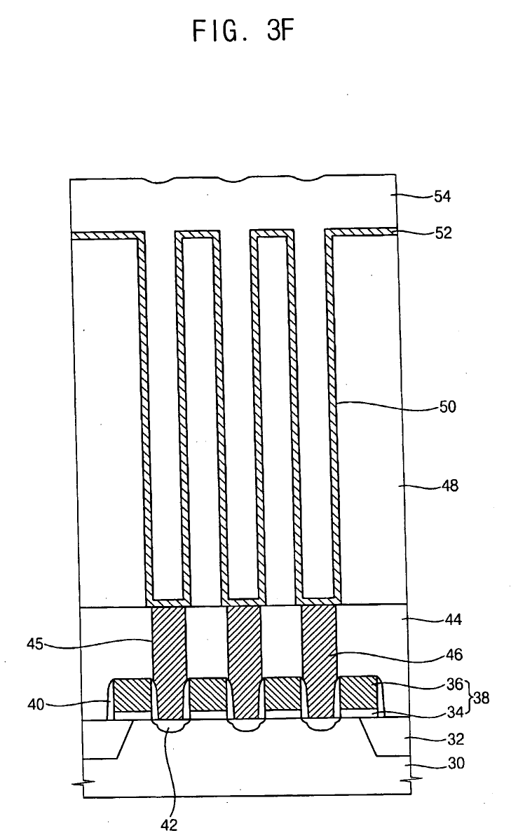

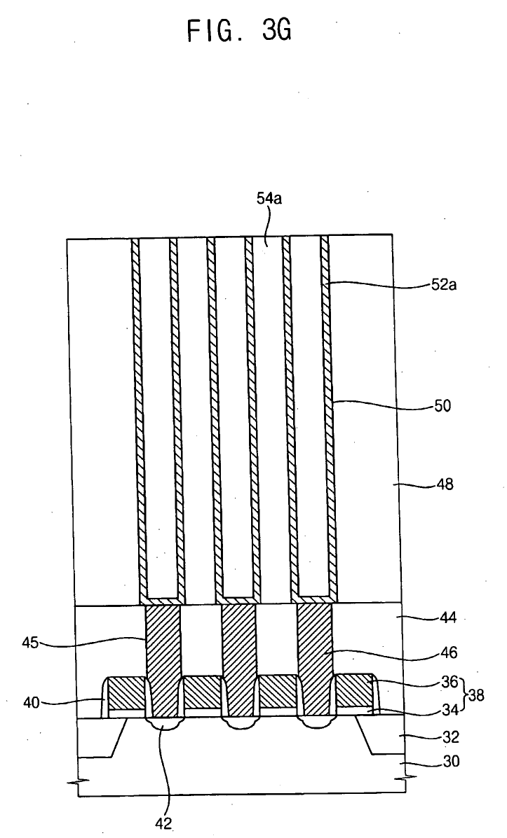

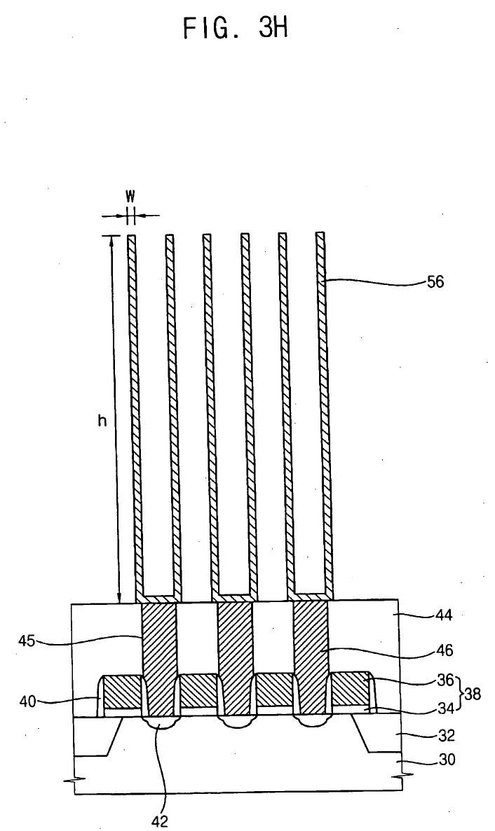

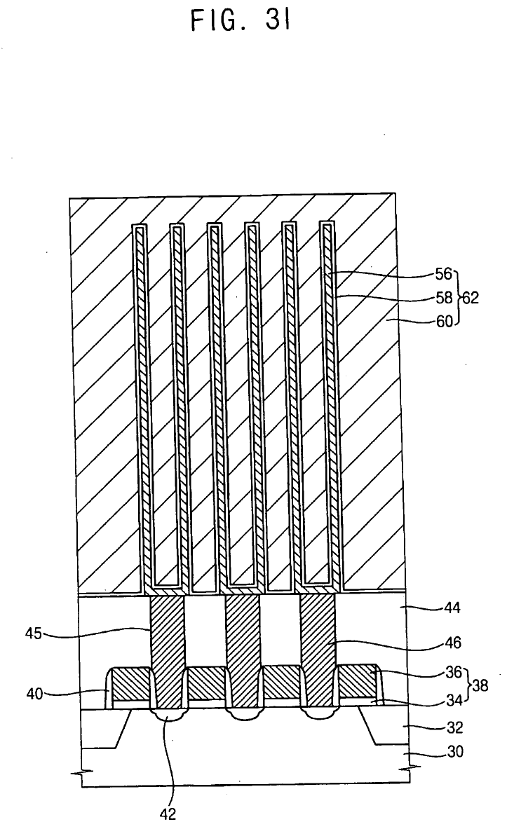

FIGS. 3A to 3I are cross sectional views illustrating processing steps for a method of forming a capacitor for semiconductor devices according to an example embodiment of the present invention.

Referring to FIG. 3A, a device isolation layer 32 may be formed on a substrate 30 using any suitable device isolation process. In at least one example embodiment of the present invention, a trench device isolation layer may be formed as a device isolation layer 32 in place of a field oxide layer. The trench device isolation may have a higher degree of integration than the field oxide layer. The device isolation layer 32 may partition the substrate 30 into an active region and a field region.

An insulation layer and a conductive layer may be formed (e.g., sequentially formed) on the substrate 30. Examples of the insulation layer include oxide, metal oxide, metal oxynitride, etc. These may be used alone or in combination with one another. For example, metal oxide may have a smaller equivalent oxide thickness (EOT) and better current leakage characteristics when applied to a semiconductor device. In at least one example embodiment, metal oxide may be deposited onto the substrate 30 using a chemical vapor deposition (CVD) process, or any other suitable deposition process, thereby forming the insulation layer on the substrate 30. Examples of the conductive layer include polysilicon, metal, metal nitride, metal silicide or any suitable metallic or semi-metallic element and/or composition with similar or substantially similar properties. These may also be used alone or in combination with each other.

When a gate conductive layer in a semiconductor device is formed into a multilayer structure, electrical characteristics of a device may be improved and the conductive layer in at least this example embodiment may have multiple layers including, for example, at least a metal layer and a metal nitride layer.

The insulation layer and the conductive layer may be patterned (e.g., sequentially patterned) to form a gate pattern 38 including a gate insulation pattern 34 and a gate conductive pattern 36 in the active region of the substrate 30. The patterning process may include, for example, an etching process using a photoresist pattern and/or a hard mask pattern including nitride as an etching mask. When the insulation layer and the conductive layer are etched using the hard mask pattern as an etching mask, the gate pattern 38 may further include a hard mask pattern (not shown) on the gate conductive pattern 36.

An ion implantation may be performed at surface portions of the substrate 30 using the gate pattern 38 as an implantation mask, so that a first doped junction area (e.g., lighter or lightly-doped junction area) may be formed at surface portions of the substrate 30 adjacent to the gate pattern 38. A spacer 40 comprising, for example, nitride may be formed on a sidewall of the gate pattern 38 by a deposition process and an etching process. Although discussed above as being formed of nitride, the spacer 40 may be formed of any suitable material.

An ion implantation may be (e.g., again) performed at surface portions of the substrate 30 using the gate pattern 38 and the spacer 40 as an implantation mask, so that a second junction area (e.g., a more heavily-doped junction area) may be formed at surface portions of the substrate 30 adjacent to the spacer 40. The second junction area may be more heavily-doped than the first junction area, and both the first and second junction areas may be formed at surface portions of the substrate 30 adjacent to the gate pattern 38 and the spacer 40, thereby forming source/drain regions 42 on the substrate 30. The source/drain regions 42 may contact a lower electrode of a capacitor.

Referring to FIG. 3B, an insulation interlayer 44 may be formed on a substrate 30 including the gate pattern 38 and a first opening 45. A top surface of the source/drain regions may be formed in the insulation interlayer 44 and exposed using a patterning process. Conductive materials such as polysilicon, metal or any other material having similar or substantially similar conductive properties may be filled into the first opening 45 forming a contact pad 46. The contact pad 46 may contact a lower electrode of a capacitor. The contact pad 46 may be formed by a deposition process, a planarization process or any other suitable process. The planarization process may include, for example, a chemical mechanical polishing (CMP) process and/or an etching process against a whole top surface of a conductive layer. Similar or substantially similar processes may also be used.

In at least this example embodiment, the contact pad 46 may include a first plug formed between the gate patterns 38 and a second plug formed on the first plug.

FIGS. 3C to 3H illustrate a method of forming a cylindrical lower electrode contacting the contact pad, according to an example embodiment of the present invention.

Referring to FIG. 3C, a preliminary mold layer 48a may be formed on the insulation interlayer 44 including the opening 46. In at least this example embodiment, the mold layer 48a may comprise oxide, or any other similar or substantially similar element or material, and may be formed by a CVD or any other similar or substantially similar process. A height of the preliminary mold layer 48a may be determined based on a height of a lower electrode of a capacitor. For example, the preliminary mold layer 48a may be formed to a height of about 1.65 μm and the lower electrode may have a height of about 1.65 μm.

The preliminary mold layer 48a may be patterned using photolithography, or any other similar process, thereby forming a second opening 50 through which the contact pad 46 may be exposed. For example, a photoresist layer (not shown) may be formed on the preliminary mold layer 48a and may be at least partially removed by a photolithography process, thereby forming a photoresist pattern on the preliminary mold layer 48a. The preliminary mold layer 48a may be at least partially etched away using the photoresist pattern as an etching mask until a top surface of the contact pad 46 is exposed. A mold layer 48 having a second opening 50 may be formed on the substrate 30 and the contact pad 46 may be exposed through the second opening 50, as shown in FIG. 3D.

Referring to FIG. 3E, a thin layer 52 may be formed on a top surface of the mold layer 48, on a sidewall of the second opening 50 and on a top surface of the contact pad 46 exposed through the second opening 50. The thin layer 52 may comprise, for example, polysilicon, metal, metal nitride, a combination thereof or any other material with similar or substantially similar properties. In at least this example embodiment of the present invention, the thin layer 52 may comprise, for example, metal nitride, which may have a higher degree of integration than, for example, polysilicon or metal. For example, titanium nitride may be deposited onto the top surface of the mold layer 48, the sidewall of the second opening 50 and the top surface of the contact pad 46 exposed through the second opening 50 by a chemical vapor deposition (CVD) or any other similar or substantially similar process thereby forming the thin layer 52 on the top surface of the mold layer 48, the sidewall of the second opening 50 and the top surface of the contact pad 46. In at least this example embodiment, the CVD process may be performed at a temperature of less than about 550° C. using a source gas including, for example, titanium tetrachloride (TiCl₄) gas, ammonia (NH₃) gas or any other suitable gas.

The thin layer 52 may be formed, for example, by an atomic layer deposition (ALD) process, a sputtering process or any other similar or substantially similar process. When the thin layer 52 is formed to a thinner thickness, the ALD process may be performed in place of the CVD process.

Referring to FIG. 3F, a sacrificial layer 54 may be formed on a resultant structure including the thin layer 52 to a thickness sufficient to fill up the second opening 50. In at least this example embodiment of the present invention, the sacrificial layer 54 may have the same or substantially the same etching rate as that of the mold layer 48. The sacrificial layer 54 may comprise, for example, oxide or any other similar or substantially similar element or material. The sacrificial layer 54 may also comprise, for example, a photoresist composition as will be discussed in more detail below.

The sacrificial layer 54 and the thin layer 52 may be removed (e.g., sequentially removed) from the mold layer 48 using a chemical mechanical polishing (CMP) process, an etching process, or any other similar or substantially similar process, against the entire surface of the sacrificial layer 54, so that the thin layer 52 and the sacrificial layer 54 may remain (e.g., only remain) in the second opening 50. As a result, the thin layer 52 may be separated by a unit cell of a memory device thereby completing a node separation against the thin layer 52, as shown in FIG. 3G Hereinafter, the thin layer 52 in the second opening 50 is referred to as a node-separated thin layer 52a and the sacrificial layer 54 in the second opening 50 is referred to as a residual sacrificial layer 54a.

Referring to FIG. 3H, the mold layer 48 and the residual sacrificial layer 54a may be removed from the substrate 30, so that a plurality of cylindrical lower electrodes 56, each of which may contact the contact pad 46, may be formed on the substrate 30. For example, the node-separated thin layer 52a may be formed onto or into the cylindrical lower electrode 56by the removal of the mold layer 48 and the residual sacrificial layer 54a. The cylindrical lower electrode 56 may have a higher aspect ratio and each of the lower electrodes 56may be arranged on the contact pad 46 closer to one another. In at least this example embodiment of the present invention, the lower electrode 56may have an aspect ratio of about 8 to about 12, inclusive. For example, the cylindrical lower electrode 56may have a height of about 1.65 μm and a width of about 0.20 μm.

In this example, the mold layer 48 and the residual sacrificial layer 54a may comprise, for example, oxide or any other similar or substantially similar element, so that the mold layer 48 and the residual sacrificial layer 54a may be removed (e.g., simultaneously removed) from the insulation interlayer 44 using a wet etching process using, for example, a Limulus Amoebocyte Lysate (LAL) solution or any other similar etching process. The LAL solution is a mixture of ammonium fluoride (NH₄F), hydrogen fluoride (HF) and water (H₂O). When the substrate 30 including the mold layer 48 and the residual sacrificial layer 54a is dipped into the LAL solution in an etching bath, the mold layer 48 and the residual sacrificial layer 54a may be removed from the insulation interlayer 44.

After the above dipping process, a cleaning process may be performed on the substrate 30 so as to remove a residual LAL solution from the substrate 30. The residual LAL solution remaining on the cylindrical lower electrode 56may cause various processing failures in a subsequent process.

The cleaning process may be performed on the substrate 30 including the cylindrical lower electrode 56using a cleaning solution of which a surface tension is smaller than that of water (hereinafter, referred to as low surface tension solution). Examples of the low surface tension solution may include isopropyl alcohol, ethanol, diluted isopropyl alcohol with water, diluted alcohol with water, etc. These may be used alone or in a mixture thereof.

The isopropyl alcohol and ethanol have a surface tension of about 22.3 dyne/cm at a temperature of about 20° C., which is smaller than that of water at the same or substantially the same temperature. As a result, although the isopropyl alcohol or the ethanol may be positioned between the neighboring lower electrodes 56in the cleaning process for removing the residual LAL solution, the neighboring lower electrodes 56may be less attracted to each other because the surface tension of the isopropyl alcohol and the ethanol may be insufficient to mutually attract the neighboring lower electrodes 56. As a result, various processing failures such as a two-bit failure caused by the breaking and/or leaning of the cylindrical lower electrodes 56may be suppressed (e.g., prevented). This may improve productivity of a semiconductor device.

A cleaning efficiency of the isopropyl alcohol and the ethanol may be lower than that of the diluted the isopropyl alcohol and the ethanol with water, so that the diluted the isopropyl alcohol and the ethanol with water may be used as the lower surface tension solution for removing the residual LAL solution from the substrate 30.

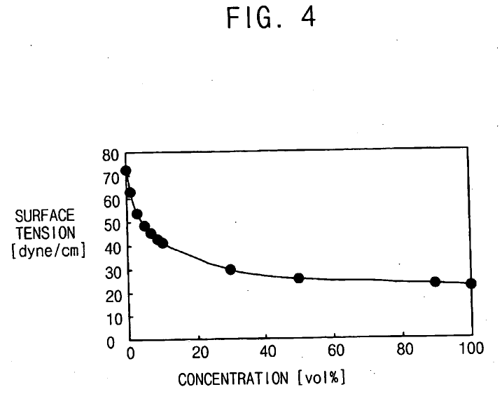

FIG. 4 is a graph showing a relation of the surface tension of a diluted isopropyl alcohol as a function of concentration according to an example embodiment of the present invention. As shown, about 10% of dilution with water may reduce the surface tension of the isopropyl alcohol to about 44% of the surface tension of water.

When the diluted isopropyl alcohol or the ethanol with water is used as the lower surface tension solution for cleaning the residual LAL solution, the neighboring lower electrodes 56may be suppressed (e.g., prevented) from being attracted to each other because the surface tension of the cleaning solution may be insufficient for mutual attraction. As a result, various processing failures caused by the breaking and/or leaning of the cylindrical lower electrodes 56may be suppressed (e.g., prevented). This may improve productivity of a semiconductor device.

In at least this example embodiment of the present invention, the cleaning process may be performed in a bath (e.g., a dip-type or any other suitable bath). When using a dip-type bath, the resultant structure including the cylindrical lower electrode 56 may be dipped into a cleaning bath containing the lower surface tension solution. When the lower surface tension solution is stored in the cleaning bath at a temperature above a boiling point thereof, the cleaning solution may be evaporated (e.g., gradually evaporated) over time, so that the lower surface tension solution may be stored in the cleaning bath at a room temperature or below the boiling point.

Although the above described example embodiment of the present invention discloses that the cleaning process is preformed after the mold layer 48 and the residual sacrificial layer 54a are removed from the insulation interlayer 44, a pre-cleaning process with water may be performed after the removal of the mold layer 48 and the residual sacrificial layer 54a and before the cleaning process with lower surface tension solution. The performance of the pre-cleaning process with water and the cleaning process with lower surface tension solution may improve a cleaning efficiency.

The neighboring lower electrodes 56may be attracted to each other due to a lower surface tension of water in the pre-cleaning process; however, the lower surface tension solution may be substituted (e.g., immediately substituted) for the water in another cleaning process. The cylindrical lower electrodes 56may not be broken and/or lean against each other despite the pre-cleaning with water having a lower surface tension.

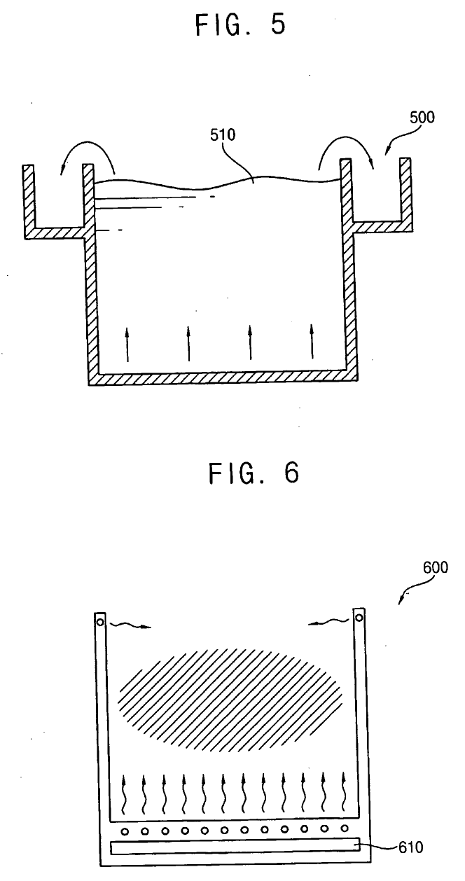

The pre-cleaning process with water may be performed using a quick dumped rinse (QDR) or any other similar or substantially similar process. For example, as shown in FIG. 5, water 510 for pre-cleaning process may be contained in a reservoir and may overflow into a subsidiary bath 500. Water may be supplied from a bottom portion of the reservoir and may fill (e.g., gradually fill) the reservoir. When the reservoir is full, water may overflow into the subsidiary bath from a top portion of the reservoir. The overflowed water may be stored in the subsidiary bath 500. The resultant structure including the cylindrical lower electrode 56may be dipped into, and rinsed by, the water in the subsidiary bath 500.

After the cleaning process for removing the residual LAL solution from the substrate 30, the resultant structure including the cylindrical lower electrode 56 may undergo a drying process. When the cleaning solution remains on the resultant structure including the cylindrical lower electrode 56, various processing failures may be generated in subsequent processes due to the remaining cleaning solution. The resultant structure including the lower electrode 56 may need to undergo the drying process to remove the remaining cleaning solution from the resultant structure.

In at least one example embodiment of the present invention, the drying process may be performed in an isopropyl alcohol vapor atmosphere. In at least this example embodiment of the present invention, the isopropyl alcohol vapor may be created by evaporating isopropyl alcohol in a processing chamber suitable for the drying process. For example, as shown in FIG. 6, a heater 610 may be positioned, for example, at or within a bottom portion of the processing chamber 600, and the isopropyl alcohol may be heated and evaporated. When the processing chamber 600 is filled (e.g., sufficiently filled) with the isopropyl alcohol vapor, the resultant structure including the cylindrical lower electrode 56 experiencing the cleaning process may be loaded into the processing chamber for the drying process. When the heater 610 heats the isopropyl alcohol at a temperature less than about 200° C., the isopropyl alcohol may not evaporate (e.g., sufficiently evaporate) due to the smaller amount of heat. When the heater 610 heats the isopropyl alcohol at a temperature higher than about 250° C., the heater 610 may be more difficult to manipulate due to a higher temperature thereof. The isopropyl alcohol may be evaporated at a temperature of about 200° C. to about 250° C., inclusive.

When the resultant structure including the cylindrical lower electrode 56 undergoes the drying process in an isopropyl alcohol vapor atmosphere, the isopropyl alcohol vapor may be substituted for the cleaning solution remaining on the resultant structure. In this example, the cleaning solution may be removed (e.g., completely removed) from the resultant structure over time.

In at least this example embodiment of the present invention, the mold layer 48 and the residual sacrificial layer 54a may be removed from the insulation interlayer 44 by a wet etching process using LAL solution or any other similar or substantially similar process, and the LAL solution may be removed using the cleaning process with a cleaning solution having a lower surface tension. The cleaning solution may be removed from the resultant structure using a drying process in an isopropyl alcohol vapor atmosphere.

A pre-cleaning process with water may be performed on the resultant structure before the cleaning process with the lower surface tension solution without breaking and/or leaning of the lower electrodes 56because the surface tension of the lower surface tension solution may be smaller or substantially smaller than that of water.

Referring to FIG. 31, a dielectric layer 58 may be formed on a top surface of the resultant structure including the cylindrical lower electrode 56 along a contour thereof.

The dielectric layer 58 may include a metal oxide layer or a multi-layer such as an oxide-nitride layer, an oxide-nitride-oxide layer or any other similar or substantially similar material or combination of materials. The metal oxide layer may have improved current leakage characteristics despite a smaller equivalent oxide thickness (EOT), so that the metal oxide layer may be used as the dielectric layer 58 in at least this example embodiment of the present invention.

In at least some example embodiments of the present invention, the dielectric layer 58 may be formed using an ALD process or any other similar or substantially similar process.

The ALD process for forming the dielectric layer 58 may include steps (e.g., sequential steps). For example, in at least one example embodiment of the present invention, source material may be provided, a residual source material may be removed or purged, an oxidizing agent may be provided and a residual oxidizing agent may be removed or purged. Performance (e.g., sequential performance) of the above steps may complete a cycle of the ALD process, and the number of times the cycle is repeated may determine a thickness of the dielectric layer 58. In at least this example embodiment of the present invention, the cycle including the steps of the ALD process may be repeated at least once, so the dielectric layer 58 comprising, for example, metal oxide may be formed on the cylindrical lower electrode 56. The source material may include a metal precursor, so that the source material includes, for example, tetrakis ethyl methyl amino hafnium (TEMAH, Hf[NC₂H₅CH₃]₄), hafnium butyl oxide (Hf(O-tBu)₄) or the like, for example, when a hafnium precursor is used in the ALD process, and includes trimethyl aluminum (TMA, Al(CH₃)₃) when an aluminum precursor is used in the ALD process. Examples of the oxidizing agent include ozone (O₃), vapor (H₂O), non-activated oxygen (O₂), oxygen (O₂) activated by plasma, remote plasma, etc. These may be used alone or in combination with one another.

For example, when the dielectric layer 58 comprises hafnium oxide, the ALD process for forming the dielectric layer 58 may include sequential steps. For example, TEMAH may be provided, a residual source material may be removed, ozone (O₃) gas may be provided, and a residual oxidizing agent may be removed. The cycle including the unit steps of the ALD process may be repeated at least once.

An upper electrode 60 may be formed on a resultant structure including the dielectric layer 58. The upper electrode 60 may have the same or substantially the same structure as the lower electrode 56, so that the upper electrode 60 may comprise, for example, polysilicon, metal, metal nitride or any other similar or substantially similar metallic or semi-metallic material. In at least one example embodiment, metal nitride may be used for forming the upper electrode 60 may be deposited onto the dielectric layer 58 using a CVD process to form the upper electrode 60. Metal nitride may have a higher degree of integration than polysilicon. In at least this example embodiment of the present invention, titanium nitride may be deposited onto the dielectric layer 58 using a CVD process using, for example, titanium tetrachloride (TiCl₄) gas and ammonia (NH₃) gas as a source gas at a temperature of less than or equal to about 550° C. to form the upper electrode 60 on the dielectric layer 58.

A capacitor 62 including the lower electrode 56, the dielectric layer 58 and the upper electrode 60 may be formed on the substrate 30. For example, the lower electrode 56 may be formed into, for example, a cylindrical shape, so that a capacitance of the capacitor 62 may be improved.

Although the above-described example embodiment discloses that the sacrificial layer 54 has the same or substantially the same etching rate as the mold layer 48, the sacrificial layer 54 may have an etching rate different from the mold layer 48. For example, the sacrificial layer 54 may comprise photoresist composition of which an etching rate may be different from that of oxide in a wet etching process.

When the sacrificial layer 54 comprises a photoresist composition, node separation may be performed against the thin layer in the same or substantially the same process as described with reference to FIG. 3G A residual sacrificial layer may be removed from the substrate by an ashing process using, for example, an oxygen gas activated by plasma. The mold layer 48 may be removed from the substrate in the same or substantially the same way as described with reference to FIG. 3H. The cleaning process and the dry process may be performed in the same or substantially the same manner as described above.

According to one or more example embodiments of the present invention, the cleaning process may be performed on a substrate including a cylindrical lower electrode using a cleaning solution having a surface tension lower than that of water. The neighboring lower electrodes 56may be no more attracted to each other because the surface tension of the cleaning solution is insufficient to mutually attract neighboring lower electrodes 56. As a result, various processing failures such as a two-bit failure caused by the breaking and/or leaning of the cylindrical lower electrodes 56may be suppress (e.g., prevented), and the capacitor including the cylindrical lower electrode may have a larger storage capacity.

Although example embodiments of the present invention have been described herein, it is understood that the present invention should not be limited to these example embodiments but various changes and modifications can be made by one skilled in the art within the spirit and scope of the present invention as hereinafter claimed.

What is claimed is:

1. A method of processing a semiconductor structure, the method comprising:
cleaning a semiconductor structure using a cleaning solution having a surface tension lower than that of water, the semiconductor structure including a plurality of patterns; and
drying the semiconductor structure in an alcohol vapor atmosphere.

2. The method of claim 1, wherein the plurality of patterns have high aspect ratios and are arranged close to one another.

3. The method of claim 1, wherein the semiconductor structure includes a lower electrode of a capacitor for a semiconductor device.

4. The method of claim 1, wherein cleaning the semiconductor structure includes dipping the semiconductor structure into a cleaning bath containing the cleaning solution.

5. The method of claim 4, wherein the cleaning solution is stored in the cleaning bath at a temperature ranging from about room temperature to about a boiling point of the cleaning solution.

6. The method of claim 1, wherein the cleaning solution includes any one selected from the group consisting of isopropyl alcohol, ethanol, diluted isopropyl alcohol, diluted alcohol and a combination thereof.

7. The method of claim 1, wherein drying the semiconductor structure includes loading the semiconductor structure into a chamber filled with the alcohol vapor evaporated from isopropyl alcohol.

8. The method of claim 7, wherein the alcohol is evaporated at a temperature of about 200° C. to about 250° C., inclusive.

9. The method of claim 1, further including,
pre-cleaning the semiconductor structure using water before cleaning the semiconductor structure.

10. The method of claim 9, wherein pre-cleaning the semiconductor structure includes,
at least partially submerging the semiconductor structure into a subsidiary bath into which water is overflowed from a reservoir, the water being supplied from a bottom portion of the reservoir and being overflowed into the subsidiary bath from a top portion of the reservoir.

11. A method of forming a capacitor for a semiconductor device, comprising:
forming a mold layer on a semiconductor substrate, the mold layer including an opening through which the substrate is at least partially exposed;
continuously forming a thin layer on a surface of the mold layer, a sidewall of the opening and a top surface of the substrate exposed through the opening;
forming a sacrificial layer on a resultant structure including the thin layer;
removing the sacrificial layer and the thin layer until the surface of the mold layer is exposed so that the sacrificial layer and the thin layer remain in the opening and the thin layer is separated by a node of a unit cell of the semiconductor device;
transforming the node-separated thin layer into a lower electrode by removing the mold layer and a residual sacrificial layer remaining in the opening;
processing the substrate according to the method of claim 1;
forming a dielectric layer on the lower electrode; and
forming an upper electrode on the dielectric layer.

12. The method of claim 11, wherein the mold layer and the residual sacrificial layer include oxide, and are removed from the substrate by wet etching using a mixture of ammonium fluoride (NH₄F), hydrogen fluoride (HF) and water.

13. The method of claim 11, wherein the mold layer includes oxide and is removed by wet etching using a mixture of ammonium fluoride (NH₄F), hydrogen fluoride (HF) and water, and the sacrificial layer includes a photoresist composition and is removed from the substrate by oxygen plasma.

14. The method of claim 11, wherein the sacrificial layer and the thin layer are removed using a chemical mechanical polishing (CMP) process or an etching process.

15. The method of claim 11, wherein cleaning the substrate on which the lower electrode is formed includes,
dipping the substrate into a cleaning bath containing the cleaning solution.

16. The method of claim 15, wherein the cleaning solution is stored in the cleaning bath at a temperature ranging from about room temperature to about a boiling point of the cleaning solution.

17. The method of claim 11, wherein the cleaning solution includes any one selected from the group consisting of isopropyl alcohol, ethanol, diluted isopropyl alcohol, diluted alcohol and a combination thereof.

18. The method of claim 11, wherein drying the substrate on which the lower electrode is formed includes,
loading the substrate including the lower electrode into a chamber filled with isopropyl alcohol vapor.

19. The method of claim 18, wherein the isopropyl alcohol is evaporated at a temperature of about 200° C. to about 250° C. to form the isopropyl alcohol vapor.

20. The method of claim 11, further including,
pre-cleaning the substrate including the lower electrode using water before cleaning the substrate on which the lower electrode is formed.

21. The method of claim 20, wherein pre-cleaning the substrate on which the lower electrode is formed includes,
dipping the substrate including the lower electrode into a subsidiary bath into which water is overflowed from a reservoir, the water being supplied from a bottom portion of the reservoir and being overflowed into the subsidiary bath from a top portion of the reservoir.
